(19) United States
(12) Patent Application Publication
(10) Pub. No.: US 2025/0225303 A1
(43) Pub. Date: Jul. 10, 2025

(54) Parameter Calculation Assistance Method, System, Apparatus and Storage Medium

(71) Applicant: PRIMARIUS TECHNOLOGIES CO., LTD., Shanghai (CN)

(72) Inventor: Keliang WANG, Shanghai (CN)

(21) Appl. No.: 19/088,599

(22) Filed: Mar. 24, 2025

Related U.S. Application Data
(63) Continuation-in-part of application No. PCT/CN2022/142569, filed on Dec. 28, 2022.

(30) Foreign Application Priority Data
Sep. 22, 2022 (CN) 202211157918.8

(51) Int. Cl. G06F 30/373

(52) U.S. Cl. CPC G06F 30/373

(57) ABSTRACT

A parameter calculation assistance method and system include: S1, receiving three-dimensional test data-set; S2, when a device model of an integrated circuit device is fitted, drawing a fitted curve regarding voltage-current-capacitance in a form of data point bit in a visualization interface according to a test data group; and S3, in response to a user-defined selection rule editor being configured in the visualization interface, inputting a selection operation algorithm required for parameter selection on the fitted curve within visualization interface; and based on selection operation algorithm being configured in the user-defined selection rule editor, when a selection operation of the fitted curve in the visualization interface is performed, selecting the data point bit adapted to a selection operation rule in a selection region for calculating a parameter of the device model.

### CROSS REFERENCE TO RELATED APPLICATIONS

This application is a Continuation-in-Part of PCT/CN2022/142569 filed on Dec. 28, 2022, for which priority is claimed under 35 U.S.C. § 120, and this application claims priority of application No. 202211157918.8 filed in China on Sep. 22, 2022 under 35 U.S.C. § 119, the entire contents of all of which are hereby incorporated by reference.

### TECHNICAL FIELD

The present disclosure relates to the technical field of computer-aided design, particularly to a parameter calculation assistance method, a system, an apparatus, and a storage medium.

### BACKGROUND ART

In the existing parameter optimization process of semiconductor device modeling, an interface program is used to assist parameter adjustment, and the process of parameter adjustment is displayed with real-time graphical information. Based on this, a technical solution has been developed, which is capable of real-time parameter feedback adjustment to an observation simulation curve for the data selection and extraction of a device model. However, in the current data selection and extraction solution, a skilled person needs to firstly select an optimization range on a data display graph, and then perform optimization according to the selected range. For certain cases, such as selecting the data range with a ±0.5V offset from the threshold voltage, or making manual selections, the process becomes very challenging because it requires manually calculating the threshold voltage for each data point and its corresponding curve. At present, the automatic selection can only be achieved by setting a complicated interface to assist the selection of model engineer type data range.

### SUMMARY OF THE INVENTION

By providing a parameter calculation assistance method, a system, an apparatus, and a storage medium, the embodiments of the present application solve the technical problems in the prior art that when selection operations are performed before parameter calculation, individual selections or batchselections, resulting in a technical problem of tedious operations and complicated calculations, and using a user-defined selection rule editor, the selection operations before parameter calculation can be defined, the calculation amount is reduced, the calculation steps are simplified and the parameter selection efficiency is improved.

In a first aspect, the embodiments of the present application provide a parameter calculation assistance method, the method comprising:
S1, receiving a three-dimensional test data set for an integrated circuit device, wherein the three-dimensional test data set includes multiple test data groups corresponding to voltage, current and capacitance, which are obtained by testing the integrated circuit device under different test conditions;
S2, in response to the configuration of a user-defined condition screening item within a visualization interface, after screening and classifying the received three-dimensional test data sets, constituting a plurality of groups of self-defined test data sets; and when a device model of the integrated circuit device is fitted with selecting any one group of the self-defined test data sets, drawing a fitted curve regarding voltage-current-capacitance in a form of a data point bit in the visualization interface according to several discrete test data groups; and
S3, in response to the configuration of a user-defined rule selection editor within the visualization interface, inputting a selection operation algorithm required for parameter selection on the fitted curve in the visualization interface; and based on the selection operation algorithm being configured in the user-defined selection rule editor, when a selection operation of the fitted curve within the visualization interface is performed, selecting the data point bit adapted to the selection operation rule within the selection region for calculating a parameter of the device model.

Further, a plurality of filters is utilized in the selection operation algorithm to filter the parameter variables.

Further, a self-defined filter code is utilized in the selection operation algorithm, the self-defined filter code including:

<graph description>
(g(<filter condition>[ , prop][ , <prop>=<value>]...) , [ ,
prop][ , <prop>=<value>]...),
x(<filter condition>[, prop][, <prop>=<value>]...),
p(<filter condition>[, prop][, <prop>=<value>]...) .

Further, a user-defined variable setting filtering condition is supported in the selection operation algorithm.

Further, expression operations, quad operations, and logical operations are supported by filtering conditions in g, x, and p axes.

Further, an equalizer is also configured in the visualization interface of step S2 to adjust the test data group in the current self-defined test data set, so that the shape of the actual fitted curve currently drawn is aligned with the target curve already plotted in the visualization interface.

Further, the fitted curve regarding voltage-current-capacitance in step S2 can be one or more of a current-voltage curve, a capacitance-voltage curve, and a current-capacitance curve.

In a second aspect, the embodiments of the present application provide a parameter calculation assistance system, including:
a data receiving module configured to receive a three-dimensional test data set of an integrated circuit device, wherein the three-dimensional test data set includes multiple test data groups related to voltage, current and capacitance obtained by testing the integrated circuit device under various conditions;
a curve plotting module configured to respond to a user-defined filter option in the visualization interface, for filtering and categorizing the received three-dimensional test dataset, thereby forming multiple sets of customized test data; and when a device model of the integrated circuit device is fitted with selecting any one group of the self-defined test dataset, plotting a fitted curve regarding voltage-current-capacitance in a form of a data point bit in the visualization interface according to several discrete test data groups;
a parameter selection module configured to respond to a user-defined selection rule editor in the visualization interface, for inputting a selection operation algorithm required to choose parameter for the fitted curve in the visualization interface; and based on the selection operation algorithm configured in the user-defined selection rule editor in advance, when a selection operation of the fitted curve in the visualization interface is performed, selecting the data point bit adapted to the selection operation rule in a selection region as a parameter of the device model.

In a third aspect, the embodiment of the present application provides an electronic apparatus, including a memory and a processor, the memory having stored thereon an instruction, the memory and the processor being interconnected by a wire, the processor calling the instruction in the memory to implement the parameter calculation assistance method according to any one of the first aspect.

In a fourth aspect, the embodiment of the present application provides a computer-readable storage medium, the computer-readable storage medium storing a computer program, wherein the computer program, when executed by a processor, implements the parameter calculation assistance method according to any one of the first aspect.

The technical solutions provided by the embodiments of the present disclosure at least have the following technical effects:

Since a user-defined selection rule editor is used, a selection operation algorithm required for performing parameter selection on the fitted curve in the visualization interface can be input in the user-defined selection rule editor so as to define a selection operation, thereby converting a complicated manual selection or graphical interface setting into a simple text setting, which is convenient to use and improves the setting efficiency and expandability of support for special functions, and at the same time can support a user-defined setting so as to facilitate setting a more complicated operation.

### BRIEF DESCRIPTION OF THE DRAWINGS

FIG. 1 is a flowchart of a parameter calculation assistance method in Embodiment 1 of the present disclosure;

FIG. 2 is a block diagram of a parameter calculation assistance system in Embodiment 2 of the present disclosure; and

FIG. 3 is a block diagram of an electronic apparatus in Embodiment 3 of the present disclosure.

### DETAILED DESCRIPTION OF THE INVENTION

The following detailed description makes reference to the accompanying drawings, which are an integral part of this specification. The illustrative implementations described in the detailed description, drawings, and claims are not intended to be limiting. Other implementations may be utilized, and other changes may be made without departing from the spirit or scope of the subject matter of the present disclosure. It will be understood that the various aspects of the present disclosure generally described and illustrated in the accompanying drawings may be configured, substituted, combined, and designed with different constructions, all of which are explicitly considered to be a part of the present disclosure.

At present, in the semiconductor device modeling technology adopted by the applicant, the parameter adjustment operation depends on the experience of an operator of a semiconductor manufacturing company. After combining a graphical display with an equalizer, manual adjustment is performed, and in the adjustment process, an equalizer is used to trigger a parameter adjustment message, and a semiconductor device modeling platform performs calculations according to parameter adjustment information corresponding to the equalizer, and displays the calculation results graphically specifically, a fitted curve relating to voltage-current-capacitance can be drawn using a test data group in a current self-defined test data set. However, since there is a certain difference between a current fitted curve and a curve required by a target, in this embodiment, an equalizer is used to adjust the current fitted curve to reduce the difference between the two curves. Although the current fitted curve and the target curve cannot completely coincide, it effectively reduces the discrepancy to a certain extent. After determining a fitted curve in the visualization interface, based on the fitted curve being composed of multiple data point bits, the data point bits in the present embodiment can be selected. When batch selection is performed in a selection region, the present disclosure provides a self-defined selection rule, and based on the self-defined selection rule, during a batch selection operation, only a part of the data point bits is selected to perform parameter calculation.

Therefore, in order to better understand the above-mentioned technical solutions, a detailed description will be given below with reference to the accompanying drawings and specific embodiments.

### Embodiment 1

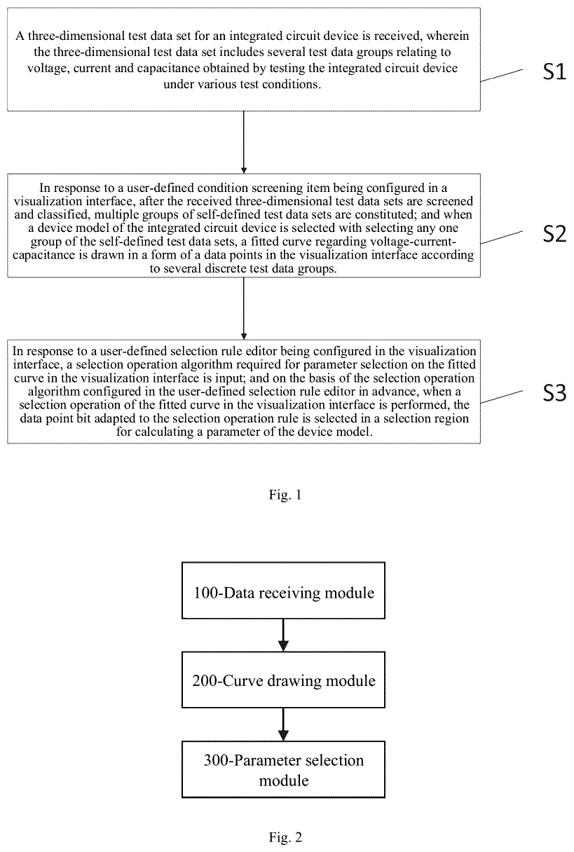

As shown in FIG. 1, an embodiment of the present disclosure provides a parameter calculation assistance method, which includes the following steps.
Step S1: A three-dimensional test data set for an integrated circuit device is received, wherein the three-dimensional test data set includes several test data groups relating to voltage, current and capacitance obtained by testing the integrated circuit device under various test conditions.

The three-dimensional test data set in this embodiment is composed of several three-dimensional test data groups, and each three-dimensional test data group includes [voltage, current and capacitance]. Therefore, when a two-dimensional curve is fitted, it can be understood that one of the data is a fixed value. For example, when the voltage is fixed, the current and the capacitance exhibit a linear relationship, and the fitted curve is drawn; or, for example, the current is fixed, the voltage and the capacitance are in a linear relationship, and a fitted curve is drawn; or when the capacitance is fixed, the voltage and the current are in a linear relationship, and a fitted curve is drawn.

The integrated circuit device in this embodiment may be, but is not limited to, the following devices: an MOSFET transistor, a silicon on insulator (SOI), a fin field-effect transistor (FinFET), a bipolar junction transistor (BJT), a heterojunction bipolar transistor (HBT), a thin-film transistor (TFT), a metal-semiconductor contact field-effect transistor (MESFET), a diode, a resistor or an inductor, etc. On such a basis, the determined device model may be, but is not limited to, BSIM3, BSIM4, BSIM6, BSIM-CMG, BSIM-IMG, BSIMSOI, UTSOI, HiSIM2, HiSIM_HV, PSP, GP-BJT, or RPITFT.

The test data group in this embodiment may be obtained by testing the integrated circuit device under different test conditions. Various types of test conditions in this embodiment may be combined to form new test conditions. For example, the test conditions may be different dimensions of the integrated circuit device (e.g. different channel length, channel width), different voltage bias conditions (e.g. the bias voltage Vbs between the body and the source, and different source and drain voltages Vds, etc.), as well as different temperature conditions. Different types of test conditions may be combined into a new group of test conditions which are used to describe the physical characteristics of the integrated circuit device under test and the test environment, such as the device's channel length, width, and bulk bias voltage of the device. It should be noted that the integrated circuit devices in this embodiment do not refer to a particular physical device but rather to a generic term for a class of devices fabricated using the same integrated circuit process. For example, two integrated circuit devices fabricated using the same process but differing only in channel width may be considered as the same integrated circuit device. Therefore, testing the integrated circuit device under each group of test conditions may produce a corresponding test data group, which may be current, voltage, and capacitance. In this manner, the test data obtained under a plurality of groups of test conditions constitutes one test data set. In some other embodiments, the test data group may be varied or adjusted according to the test conditions and test requirements under which the test is performed, and the present disclosure is not limited thereto. For example, derived electrical parameters may include parameters such as Idin, saturated leakage current ldsat, maximum transconductance maxGm, Vtlin, saturated threshold voltage Vtsat, Vtgm, etc. It may also include electrical output parameters such as Gm, Gds, etc. For further description of these parameters, reference may also be made to the description in the BSIM model or other models. These electrical parameters may vary with voltage.
Step S2: In response to a user-defined condition screening item being configured in a visualization interface, after the received three-dimensional test data sets are screened and classified, multiple groups of self-defined test data sets are constituted; and when a device model of the integrated circuit device is selected with selecting any one group of the self-defined test data sets, a fitted curve regarding voltage-current-capacitance is drawn in a form of a data points in the visualization interface according to several discrete test data groups.

By way of further illustration, data point in this embodiment can be understood to mean that each test data group occupies one data point in the visualization interface, and that a single data point bit is clickable.

The user-defined condition screening item in the present embodiment can be understood to divide the received three-dimensional test data set into data under different bias conditions. For example, when the screening condition is a fixed voltage, then based on the fixed voltage, all the test data groups under a common fixed voltage can be extracted, and a self-defined test data set based on the fixed voltage can be constituted. The screening condition is not limited to a fixed voltage but may be a fixed current or a fixed capacitance.

To further illustrate, the visualization interface in this embodiment not only displays a fitted curve drawn from the current self-defined test data set of interest, but also draws a target curve based on the test conditions. The target curve can be understood as theoretical data. Under a certain test condition, the theoretically achievable test data group is plotted as the target curve. In this embodiment, a visualization interface is used to simultaneously present the fitted curve drawn from the test data group in the current self-defined test data set and the target curve under the same condition, and a person skilled in the art would have been able to directly adjust the fitted curve using an equalizer according to the view and the error operation can be reduced without reconfiguring a screening condition, and the test data group closest to the target can be selected. Therefore, in the present embodiment, an equalizer is further configured in the visualization interface of step S2 for adjusting the test data group in the current self-defined test data set to bring a shape of an actual fitted curve currently drawn towards a target curve already drawn in the visualization interface. That is, the equalizer is used to adjust the shape of the fitted curve such that it approaches the target curve until the final fitted curve is determined after the adjustment cannot be continued. The fitted curve is plotted in a form of data point bit in the visualization interface, and each data point bit represents one test data group, that is, the test data group determined according to the data point bit in a final fitted curve is the test data group closest to theoretical data in the present embodiment.

The fitted curve regarding voltage-current-capacitance in step S2 can be one or more of a current-voltage curve, a capacitance-voltage curve, and a current-capacitance curve. Furthermore, different display interfaces can be used in the visualization interface to display the fitted curve drawn from the test data group in different self-defined test data sets.
Step S3: In response to a user-defined selection rule editor being configured in the visualization interface, a selection operation algorithm required for parameter selection on the fitted curve in the visualization interface is input; and on the basis of the selection operation algorithm configured in the user-defined selection rule editor in advance, when a selection operation of the fitted curve in the visualization interface is performed, the data point bit adapted to the selection operation rule is selected in a selection region for calculating a parameter of the device model.

In this embodiment, it can be seen from step S3 that a selection assistance method before parameter calculation on the basis of a visualization interface is implemented. If there is no technical solution in step S3, when a batch selection operation is performed in a certain region, all the data point bits in the selection area can be directly clicked and pulled, but not all the data point bits meet the selection requirements; and when parameter calculation is performed, if the test data groups corresponding to all the data point bits in the selection area are subjected to parameter calculation, the calculation amount will be large, there will be many invalid operations and the calculation efficiency is very low. On such a basis, the present disclosure provides the technical solution in step S3.

In the present embodiment, a plurality of filters is employed in the selection operation algorithm for filtering of parameter variables. A self-defined filter code is employed in the selection operation algorithm, the self-defined filter code including:

<graph description>
(g(<filter condition>[, prop][, <prop>=<value>]...), [, prop][,
<prop>=<value>]...),
x(<filter condition>[, prop][, <prop>=<value>]...),
p(<filter condition>[, prop][, <prop>=<value>]...) .

A user-defined variable setting filtering condition is supported in the selection operation algorithm. Expression operations, quad operations, and logical operations are supported by filtering conditions in G, X, and P axes.

Further examples and explanations are provided for self-defined filter code. “<graph description>”: representation of selecting a graph type filter, and inputting Id_vg in the visualization interface, namely, a graph representing the variation of d port current with the variation of Vg; “[, <prop>] [, <prop>=<value>]”: reference to a graph type filter, which is an optional parameter. For example, “gm, scale=1” means to select a graph wherein sn y-axis output is gm (dy/dx) and the y-axis coordinates are of the log scale type; “g (<filter condition>)”: a graph filter, where “<filter condition>” can be a constant number, a self-defined variable, a self-defined expression, or a program embedded extraction algorithm, such as MinVds (a graph representing a smallest graph constant Vds); “[, <prop>] [, <prop>=<value>]”: being expressed as a graph filter reference, which is an optional parameter. For example, g (All, step=2) is expressed as selecting a graph of which graph constants are in an increasing order by picking points with a step size of 2 among all the graphs selected as conforming graph filtering; “x (<filter condition>)”: being an X-axis filter, wherein <filter condition>can be a constant number, a self-defined variable and a self-defined expression, such as vth (representing the vgs corresponding to a turn-on voltage of a graph device); “[, <prop>] [, <prop>=<value>]”: representation of an X-axis filter reference, which is an optional reference; “p (<filter condition>)”: being a P-axis filter, wherein <filter condition>can be a constant number, a self-defined variable and a self-defined expression, and the vgs corresponding to the turn-on voltage of a graph device is represented by vth; “[, <prop>] [, <prop>=<value>]”: indication of the P-axis filter reference, which is an optional reference.

In one embodiment, the following contents are input at the user-defined selection rule editor: the rule “Id_vg (g (MinVds), gm, scale=1), x (vth-0.05, vth*1.1, point=15), p (−1.05, 0, points=2)” can be understood to mean that for a fitted curve of type Id_vg in the visualization interface, the Y-axis output of the fitted curve uses a mathematical transformation dy/dx to calculate gm and shows the graph in log, and two curves from −2 up to 0.5 time of a maximum value range of the P-axis are selected in the direction of P-axis when selecting in the P-axis direction from −2 to 0.5 times the P-axis, two curves within the maximum value range of the P-axis are selected. If fewer than two curves are available, all available curves are selected. If there are less than two curves, all curves are selected. From each selected curve, 15 points are selected from vth−0.5 to vth*1.1 in an X direction, and all points are selected if there are less than 15 points.

It can be seen that the present embodiment configures a user-defined selection rule editor in the visualization interface, and then defines a selection operation by inputting a selection operation algorithm required for parameter selection on the fitted curve in the visualization interface. It can be seen that the present embodiment converts a complex manual selection or graphical interface setting into a simple text setting, which is convenient to use and improves the setting efficiency and expandability of support for special functions, and at the same time can support user-defined settings, which is convenient to set more complex operations.

### Embodiment 2

Referring to FIG. 2, an embodiment of the present application provides a parameter calculation assistance system, using the method of the embodiment. The system includes the following modules.

A data receiving module 100 is configured for receiving a three-dimensional test data set of an integrated circuit device, wherein the three-dimensional test data set includes several test data groups relating to voltage, current and capacitance obtained by testing the integrated circuit device under different test conditions.

A curve drawing module 200 is configured for, in response to a user-defined condition screening item being configured in a visualization interface, after screening and classifying the received three-dimensional test data sets, constituting a plurality of groups of self-defined test data sets; and when a device model of the integrated circuit device is fitted with selecting any one group of the self-defined test data sets, drawing a fitted curve regarding voltage-current-capacitance in a form of a data point bit in the visualization interface according to several discrete test data groups.

A parameter selection module 300 is configured for, in response to a user-defined selection rule editor being configured in the visualization interface, inputting a selection operation algorithm required for parameter selection on the fitted curve in the visualization interface; and on the basis of the selection operation algorithm configured in the user-defined selection rule editor in advance, when a selection operation of the fitted curve in the visualization interface is performed, selecting the data point bit adapted to the selection operation rule in a selection region as a parameter of the device model.

### Embodiment 3

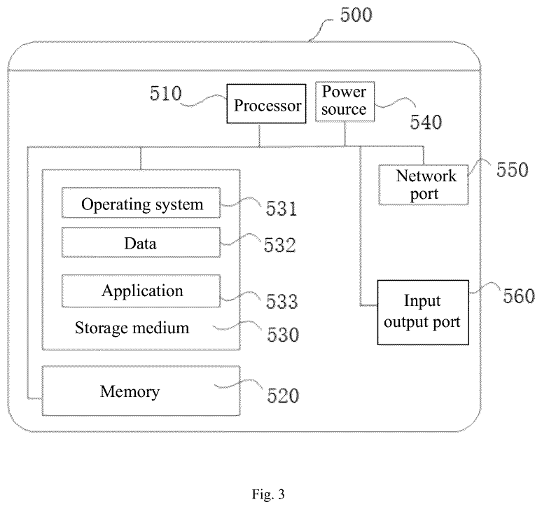

With reference to FIG. 3, an embodiment of the present application provides an electronic apparatus, including a memory and a processor, the memory having stored thereon an instruction, the memory and the processor being interconnected by a wire, the processor calling the instruction in the memory to implement the parameter calculation assistance method according to any one of the embodiments 1. The electronic apparatus 500 may vary widely in configuration or performance and may include one or more central processing units (CPU) 510 (e.g. one or more processors) and memory 520, one or more storage media 530 (e.g. one or more mass storage devices) storing applications 533 or data 532. Here, the memory 520 and the storage medium 530 may be transient storage or persistent storage. A program stored on storage medium 530 may include one or more modules (not shown), each of which may include a series of instruction operations on electronic apparatus 500.

Further, the processor 510 may be configured to communicate with a storage medium 530 to perform a series of instruction operations on the storage medium 530 on the electronic apparatus 500.

The electronic apparatus 500 may also include one or more power sources 540, one or more wired or wireless network ports 550, one or more input output ports 560, and/or one or more operating systems 531, such as Windows server, etc. A person skilled in the art can understand that the electronic apparatus structure shown in FIG. 3 does not constitute a limitation on the electronic apparatus and may include more or fewer components than shown in the diagram, or combine certain components or different component arrangements.

### Embodiment 4

In a fourth aspect, an embodiment of the present application provides a computer-readable storage medium, the computer-readable storage medium having stored thereon a computer program, wherein the computer program, when executed by a processor, implements the parameter calculation assistance method according to any one of Embodiment 1. The computer-readable storage medium may be a non-volatile computer-readable storage medium or a volatile computer readable storage medium. The computer-readable storage medium has stored thereon an instruction which, when executed on a computer, causes the computer to perform the steps of the parameter calculation assistance method of Embodiment 1.

The parameter calculation assistance method, if implemented in the form of program instruction and sold or used as stand-alone products, may be stored in a computer-readable storage medium. Based on such an understanding, the technical solutions of the present disclosure, either per se or in part making a contribution to the prior art or in their entirety, may be embodied in the form of a software, which computer software may be stored in one storage medium, including instructions to cause one computer device, which may be a personal computer, a server, or a network device, to perform all or part of the methods of the various embodiment methods of the present disclosure. The storage medium described above may include various media that may store program codes, such as a U-disk, a removable hard disk, a read-only memory (ROM), a random-access memory (RAM), a magnetic or optical disk.

A person skilled in the art will appreciate that embodiments of the present disclosure may be provided as a method, a system, or a computer program product. Accordingly, the present disclosure may take the form of an entirely hardware embodiment, an entirely software embodiment or an embodiment combining software and hardware aspects. Moreover, the present disclosure can take the form of a computer program product embodied on one or more computer-usable storage media having computer-usable program codes embodied therein (including but not limited to a disk storage, a CD-ROM, an optical storage, etc.).

The present disclosure is described with reference to flowchart illustrations and/or block diagrams of methods, devices (systems), and computer program products according to embodiments of the present disclosure. It will be understood that each flow and/or block of the flowcharts and/or block diagrams, and combinations of flows and/or blocks in the flowcharts and/or block diagrams, can be implemented by computer program instructions. These computer program instructions may be provided to a processor of a general purpose computer, special purpose computer, embedded processor, or other programmable data processing device to produce a machine, such that the instructions, which are executed via the processor of the computer or other programmable data processing device, create means for implementing the functions specified in the flow or flows in the flowchart and/or block or blocks in the block diagram.

These computer program instructions may also be stored in a computer-readable memory that can direct a computer or other programmable data processing device to function in a particular manner, such that the instructions stored in the computer-readable memory produce an article of manufacture including instruction apparatus which implements the function(s) specified in one flow or multiple flows in the process flowchart and/or one block or multiple blocks in the block diagram.

These computer program instructions may also be loaded onto a computer or other programmable data processing device to cause a series of operational steps to be performed on the computer or other programmable devices to produce a computer implemented process such that the instructions which are executed on the computer or other programmable devices provide steps for implementing the function(s) specified in one flow or multiple flows in the process flowchart and/or one block or multiple blocks in the block diagram.

While preferred embodiments of the present disclosure have been described, additional variations and modifications to these embodiments will occur to a person skilled in the art once the basic inventive concept is known. Therefore, it is intended that the appended claims be interpreted as including the preferred embodiments and all variations and modifications that fall within the scope of the present disclosure.

It will be apparent to a person skilled in the art that various modifications and variations can be made in the present disclosure without departing from the spirit or scope of the disclosures. Thus, it is intended that the present disclosure covers the modifications and variations of this disclosure provided they come within the scope of the appended claims and their equivalents.

1. A parameter calculation assistance method, comprising:
S1, receiving a three-dimensional test data set of an integrated circuit device, wherein the three-dimensional test data set comprises several test data groups relating to voltage, current and capacitance obtained by testing the integrated circuit device under different test conditions;
S2, in response to a user-defined condition screening item being configured in a visualization interface, after screening and classifying the received three-dimensional test data sets, constituting a plurality of groups of self-defined test data sets; and when a device model of the integrated circuit device is fitted with selecting any one group of the self-defined test data sets, drawing a fitted curve regarding voltage-current-capacitance in a form of a data point bit in the visualization interface according to several discrete test data groups; and
S3, in response to a user-defined selection rule editor being configured in the visualization interface, inputting a selection operation algorithm required for parameter selection on the fitted curve in the visualization interface; and on the basis of the selection operation algorithm being configured in the user-defined selection rule editor, when a selection operation of the fitted curve in the visualization interface is performed, selecting the data point bit adapted to the selection operation rule in a selection region for calculating a parameter of the device model.

2. The parameter calculation assistance method according to claim 1, wherein a plurality of filters are employed in the selection operation algorithm for filtering of parameter variables.

3. The parameter calculation assistance method according to claim 2, wherein a self-defined filter code is employed in the selection operation algorithm, the self-defined filter code comprising:
```
  <graph description>
  (g(<filter
condition>[, prop][, <prop>=<value>]...), [, prop][,
<prop>=<value>]...),
  x(<filter condition>[, prop][, <prop>=<value>]...),
  p(<filter condition>[, prop][, <prop>=<value>]...) .
```

4. The parameter calculation assistance method according to claim 3, wherein a user-defined variable setting filtering condition is supported in the selection operation algorithm.

5. The parameter calculation assistance method according to claim 3, wherein expression operations, quad operations, and logical operations are supported by filtering conditions in g, x, and p axes.

6. The parameter calculation assistance method according to claim 1, wherein an equalizer is further configured in the visualization interface of step S2 for adjusting the test data group in the current self-defined test data set to bring a shape of an actual fitted curve currently drawn towards a target curve already drawn in the visualization interface.

7. The parameter calculation assistance method according to claim 1, wherein the fitted curve regarding voltage-current-capacitance in step S2 can be one or more of a current-voltage curve, a capacitance-voltage curve, and a current-capacitance curve.

8. A parameter calculation assistance system, comprising:
a data receiving module configured for receiving a three-dimensional test data set of an integrated circuit device, wherein the three-dimensional test data set comprises several test data groups relating to voltage, current and capacitance obtained by testing the integrated circuit device under different test conditions;
a curve drawing module configured for, in response to a user-defined condition screening item being configured in a visualization interface, after screening and classifying the received three-dimensional test data sets, constituting a plurality of groups of self-defined test data sets; and when a device model of the integrated circuit device is fitted with selecting any one group of the self-defined test data sets, drawing a fitted curve regarding voltage-current-capacitance in a form of a data point bit in the visualization interface according to several discrete test data groups; and
a parameter selection module configured for, in response to a user-defined selection rule editor being configured in the visualization interface, inputting a selection operation algorithm required for parameter selection on the fitted curve in the visualization interface; and on the basis of the selection operation algorithm configured in the user-defined selection rule editor in advance, when a selection operation of the fitted curve in the visualization interface is performed, selecting the data point bit adapted to the selection operation rule in a selection region as a parameter of the device model.

9. An electronic apparatus, comprising a memory and a processor, the memory having stored thereon an instruction, the memory and the processor being interconnected by a wire, the processor calling the instruction in the memory to implement the parameter calculation assistance method according to claim 1.

10. A computer-readable storage medium, the computer-readable storage medium having stored thereon a computer program, wherein the computer program, when executed by a processor, implements the parameter calculation assistance method according to claim 1.
